(19) United States
(12) Patent Application Publication
(10) Pub. No.: US 2019/0383481 A1
(43) Pub. Date: Dec. 19, 2019

(54) LIGHTING CORD FOR DECORATIONS

(71) Applicant: Aiboling (Xiamen) technology co, ltd, Xiamen (CN)

(72) Inventor: Tieying SONG, Xiamen (CN)

(73) Assignee: Aiboling (Xiamen) technology co, ltd, Xiamen (CN)

(21) Appl. No.: 16/428,969

(22) Filed: Jun. 1, 2019

(30) Foreign Application Priority Data
Jun. 2, 2018 (CN) 201810560015.1

(51) Int. Cl. F21V 33/00; H05K 1/18; H05K 3/32; H05K 3/28; F21V 23/02; F21V 19/00; F21V 23/04; F21K 9/64; F21K 9/90; A44C 15/00

(52) U.S. Cl. CPC F21V 33/0008; H01L 25/13; H05K 3/328; H05K 3/281; F21V 23/02; F21V 19/0015; F21V 23/04; F21K 9/64; F21K 9/90; A44C 15/0015; H05K 2201/10053; H05K 2201/10106; H05K 2201/10037; H05K 2201/2009; H05K 1/189

(57) ABSTRACT

A lighting rope for an accessory includes a power control unit, a rope sleeve, and a flexible printed circuit board provided inside and extending along the rope sleeve. The flexible printed circuit board is sleeved with the rope sleeve by using a heat shrinkable film wrapping process. The flexible printed circuit board is provided in a length direction with a plurality of light-emitting diodes (LEDs) arranged at intervals. The power supply control unit includes a push button and a power supply battery. The LEDs are powered by the power supply battery and controlled by the push button to emit light. A semiconductor process is used to mount the LEDs on the flexible printed circuit board and the heat shrinkable film wrapping process is used to wrap the rope sleeve outside the flexible printed circuit board, greatly reducing the diameter of the existing lighting rope.

### CROSS REFERENCE TO THE RELATED APPLICATIONS

This application is based upon and claims priority to Chinese Patent Application No. 201810560015.1, filed on Jun. 2, 2018, the entire contents of which are incorporated herein by reference.

### TECHNICAL FIELD

The present invention relates to a lighting rope for an accessory.

### BACKGROUND

People who love fashion and beauty like to wear various accessories. In particular, people wear bead strings, gems and the like, where the beads and gems are embedded into clothes and jewelry. A guide rope for jewelry usually has a basic embellishment. More requirements have been placed on jewelry, such as having diverse colors, light emitting, illumination, and alarming as the time passes and people place more emphasis on their function. The existing guide ropes are made of silk linen or DACRON and they cannot emit light.

When a conventional electrical wire is used as the guide rope, the electrical wire is rigid, lacks flexibility, is oversized and is not waterproof when the wire is connected to a Light Emitting Diode (LED). Furthermore, the wire cannot easily threaded the accessories.

### SUMMARY

To achieve the above-mentioned function, the present invention provides a lighting rope for accessories.

The present invention relates to a lighting rope for an accessory and comprises a power supply control unit, a rope sleeve and a flexible printed circuit board provided inside and extending along the rope sleeve, wherein the flexible printed circuit board is sleeved with the rope sleeve by using a heat shrinkable film wrapping process. The flexible printed circuit board is provided in a length direction with a plurality of light-emitting diodes (LEDs), where intervals/spacings are formed between the LEDs. The power supply control unit includes a push button and a power supply battery. The LEDs are powered by the power supply battery and are controlled by the push button in order to emit light.

A base material for the rope sleeve is one of polyvinylidene difluoride (PVDF), polyethylene (PE), ethylene-vinyl acetate (EVA), polyvinyl chloride (PVC), polyvinylidene chloride (PVDC), polytetrafluoroethylene (PTFE), and ethylene propylene diene terpolymer (EPDM).

A process temperature of the heat shrinkable film wrapping process for the rope sleeve is less than a welding temperature at which the LEDs are welded onto the flexible printed circuit board.

The flexible printed circuit board is a single-layer or a multilayer structure and is a hybrid circuit.

A reinforcing structure providing reinforcement is further provided inside the rope sleeve. The reinforcing structure abuts against the flexible printed circuit board and/or is mutually independent of the flexible printed circuit board. A material of the reinforcing structure is one of or a combination of polyimide (PI), stainless steel, aluminum foil, polyester (PET), fiberglass (FR), polytetrafluoroethylene (PTFE), polyethylene (PE), polycarbonate (PC), and polystyrene (PS).

The LEDs are provided on the side of the flexible printed circuit board. An electrode matched with the power supply battery on the flexible printed circuit board is provided with a conductive protrusion.

A hollow part of the rope sleeve is filled with a silicone material mixed with phosphor.

The LEDs are LED chips or encapsulated LED beads. The LEDs can be welded on the flexible printed circuit board by normal welding or by flip-chip welding.

The LEDs are welded on the flexible printed circuit board to form an emitting core. The heat shrinkable film wrapping process is carried out on the lighting core and the rope sleeve to form the lighting rope.

The LEDs, controlled by the power supply control unit, have one or more of the following lighting modes: a constant lighting mode, a gradient lighting mode, a round-robin lighting mode, and a flashing lighting mode.

The present invention has the following advantages.

The present invention has a semiconductor process which mounts the LEDs onto the flexible printed circuit (FPC). A width of the flexible printed circuit is between 1.0 mm and 0.5 mm. The flexible printed circuit board is sleeved with the rope sleeve by using the heat shrinkable film wrapping process. A diameter of the rope sleeve may be 2.0 mm, which is much smaller than the diameter of existing lighting ropes. The ropes having a diameter of 2 mm enables one to directly replace ordinary accessories (such as bead strings or jewelry) from the ropes. Moreover, without applying any secondary grinding to the accessory, miniaturization of the LED circuit is achieved and therefore, the diameter of the rope sleeve is small/fine and the guide ropes of the existing accessories can be replaced one-by-one without any major modification being made to the accessory structure.

Adopting the heat shrinkable film wrapping process for the rope sleeve protects the inner circuit from damage caused by friction of external objectives and therefore realizes certain functions such as waterproofing, emitting light, carrying the phosphor and enhancing a tensile resistance of the lighting rope. Adopting the heat shrinkable film wrapping process not only solves the difficulty in the bead string threading process caused by an oversized rope, but also ensures consistency of the rope diameter within the same manufacturing batch.

The material of the rope sleeve may be doped with phosphor and therefore the rope sleeve can be excited to generate spectrums of different colors and realize diversification of the colors of light, after being combined with the LEDs with different wavelength. Therefore, the rope sleeve can have a single spot which emits light or the entire body of the rope sleeve can emit light. The emitted/output light can have different colors or different color temperatures by adjusting the proportion of the phosphor added to the rope sleeve.

The LED can emit light and excite the filling material inside the rope sleeve to emit light or excite the rope sleeve itself to emit light by connecting the LED to the power supply battery, thereby realizing diverse light color from the lighting rope. The color of light can not only make the bead strings and gems more brightly colored, but also has an illumination or alarming effect when used in dark places by adjusting a working frequency of the LED with the power supply control unit.

The printed circuit board is a flexible printed circuit (FPC) board. The base material of the flexible printed circuit board may be polyester film (MYLAR) and polytetrafluoroethylene (PTFE), having certain functions such as waterproofing, insulating, and protecting the inner circuit. The flexible printed circuit board may be formed by means of laser cutting. Apart from the power supply control unit, a width of a part of the flexible printed circuit board used for the bead string can be precisely controlled below 1.0 mm, which makes the flexible printed circuit board suitable/ready for mass production. The lighting rope has an inner reinforcing structure. The reinforcing structure abuts against the flexible printed circuit board and/or is mutually independent of the flexible printed circuit board, thereby ensuring the rope body can endure large tension without breaking and has good folding resistance and tensile property.

### BRIEF DESCRIPTION OF THE DRAWINGS

The drawings described herein, forming a part of the present invention, are intended to provide a further understanding of the present invention. Schematic embodiments of the present invention and descriptions thereof are intended for explaining the present invention, rather than limiting the scope of the present invention.

FIG. 1 is a schematic diagram showing an entire/whole structure of a lighting rope for an accessory according to a preferred embodiment of the present invention;

FIG. 2 is a schematic diagram showing an inner structure of a lighting rope for an accessory according to a preferred embodiment of the present invention;

FIG. 3 is a schematic sectional view of a lighting rope for an accessory according to a preferred embodiment of the present invention (where a flexible printed circuit board is single-layered);

FIG. 4 is a schematic sectional view of a lighting rope for an accessory according to another preferred embodiment of the present invention (where a flexible printed circuit board is multiple-layered);

FIG. 5 is a schematic structural diagram showing an encapsulated LED bead used as a LED of a lighting rope for an accessory according to a preferred embodiment of the present invention;

FIG. 6 is a schematic diagram showing an encapsulated LED bead welded on a flexible printed circuit board according to a preferred embodiment of the present invention;

FIG. 7 is a schematic diagram showing a structure of a LED chip used as a LED of a lighting rope for an accessory according to a preferred embodiment of the present invention;

FIG. 8 is a schematic diagram showing a LED chip welded on a flexible printed circuit board according to a preferred embodiment of the present invention; and

FIG. 9 is a flow chart of a process of forming a lighting rope for an accessory according to a preferred embodiment of the present invention.

In the drawings:
1, lighting rope;
10, rope sleeve; 20, flexible printed circuit board; 21, copper-coating layer; 22, surface insulation heat shrinkable film; 23, bottom insulation heat shrinkable film; 30, LED; 40, power supply control unit; 41, push button; 51, reinforcing board; 52, reinforcing wire;
2, accessories.

### DETAILED DESCRIPTION OF THE EMBODIMENTS

In order to make the technical solutions and advantages of the present invention clearer and more explicit, the present invention will be further described in detail hereinafter with reference to the drawings and the embodiments. It should be understood that the specific embodiments described herein are merely used for illustrating the present invention, rather than limiting the scope of the present invention.

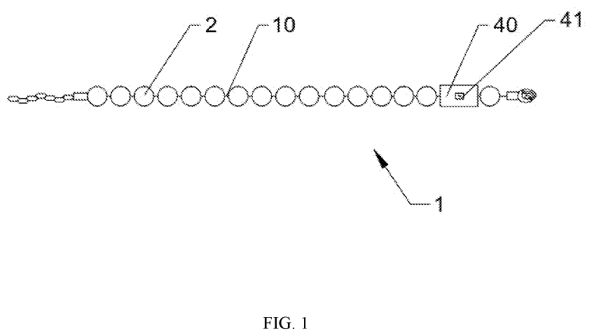

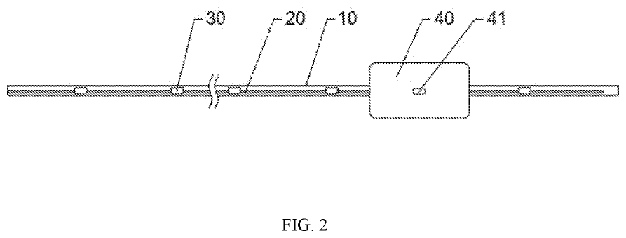

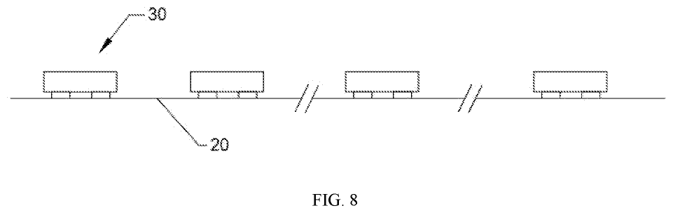

As shown in FIG. 1 to FIG. 8, the lighting rope 1 for an accessory of the present invention is used to string the accessory 2. The accessory 2 of the present invention is described below by a bead string, where a bead string is used as one example of the accessory 2. The lighting rope 1 includes the rope sleeve 10, the flexible printed circuit board (also simply referred to as FPC board) 20, the LEDs 30, and the power supply control unit 40. The flexible printed circuit board 20 is provided inside the rope sleeve 10 and extends along the rope sleeve 10. The flexible printed circuit board is provided in a length direction with a plurality of the LEDs 30, where intervals/spacings are formed between the LEDs. The power supply control unit 40 includes the push button 41 and a power supply battery (not shown). The LEDs 30 are powered by the power supply battery and are controlled by the push button 41 in order to emit light.

In the present embodiment, the flexible printed circuit board 20 is sleeved with the rope sleeve 10 by using a heat shrinkable film wrapping process. A material of the rope sleeve may be transparent or not transparent. A base material for the rope sleeve is one of polyvinylidene difluoride (PVDF), polyethylene (PE), ethylene-vinyl acetate (EVA), polyvinyl chloride (PVC), polyvinylidene chloride (PVDC), polytetrafluoroethylene, and ethylene propylene diene terpolymer (EPDM). A heat shrinking temperature of the rope sleeve 10 is between 80° C. and 260° C. Therefore, the rope sleeve has the advantages and properties of reliable mechanical strength, rigidity, flame retardant property (94V-0), good mold proof property, wear resistance, penetration resistance, heat stability, impact resistance, and low-high temperature resistance (−45° C.−260° C.). Additionally, the heat shrinkable film wrapping process can protect the inner circuit from damage caused by friction of outer objectives and therefore realizes certain functions such as waterproofing, emitting light, carrying the phosphor and enhancing a tensile resistance of the lighting rope. The rope sleeve 10 adopts the heat shrinkable film wrapping process to solve the difficulty in the bead string threading process caused by an oversized rope of existing accessories and other difficulties.

In the present embodiment, the material of the rope sleeve is filled with phosphor. The phosphor consists of fluorescent materials such as aluminate, silicate, nitride, and oxynitride. Alternatively, the phosphor may include yellow yttrium aluminum garnet (Y₃Al₅O₁₂) yellow emitting phosphor, or yellow-green LuAg, Gayag phosphor, orange silicate phosphor Zn₂SiO₄: Mn²⁺, and red nitride phosphor. Herein, red-yellow (Ca, Sr, Ba)xSiyNz:Eu nitride phosphor can be included. SrzSi₅N₈:Eu and SrzSi₅N₁₀:Eu are for applications in the blue and ultraviolet LEDs, and Cax(Eu, Tb, Yb, Er)y(Si, Al)₁₂(O, N)₁₆ with multiple light colors, mix with a nitride phosphor with high light emitting efficiency, mix with Ca-α-SiAlON are for applications in orange color and MSi₂N₂O₂:Eu²⁺ are for applications in green color. It can be mixed with various rear earth ions (such as Eu²⁺, Ce³⁺, Dy³⁺, Eu³⁺, and Mn²⁺). A nitride phosphor (Sr, Ca)AlSiN₃:Eu²⁺ emitting orange light can be matched with a phosphor CaSc₂O₄: Ce³⁺ or Ca₃(Sc, Mg)₂Si₃O₁₂:Ce³⁺ emitting green light. An oxynitride Ba₃Si₆O₁₂N₂:Eu emitting green light can substitute an oxide CaSc₂O₄:Ce³⁺ and can be matched with varying materials such as nitrogen silicide CaAlSiN₃: Eu²′ emitting orange light, a novel oxynitride Ba₃Si₆O₁₂N₂:Eu excited by an ultra-violet light and a blue light, phosphor (CaAlSiN₃: Eu²⁺) emitting red light, phosphor (α-SiAlON: Eu²⁺) emitting yellow light, phosphor (β-SiAlON: Eu²′) emitting green light, (Sr, Ba, Mg)₃Si₂O₇: Pb²⁺ (1949), BaSi₂O₅:Pb²⁺ (1960), Sr₄Si₃OBCl₄:Eu²⁺ (1967), BaSi₂O₅:Pb²⁺ (1960), phosphor SrGa₂S₄: Eu²⁺ emitting green light, and phosphor SrS: Eu²′ emitting red light.

The LEDs with different wavelength can emitting different color lights, the phosphor can be excited by different colors LEDs, realizing the diversification of the colors of light and realizing an effect that a single spot of the rope sleeve or the entire body of the rope sleeve emits light. Moreover, an output of light with different colors or color temperatures can be realized by adjusting the proportion of the phosphor added to the rope sleeve.

In the present invention, a reinforcing structure providing reinforcement is further provided inside the rope sleeve 10. The reinforcing structure abuts against the flexible printed circuit board 20 and/or is mutually independent of the flexible printed circuit board 20. A double reinforcing structure is provided. That is, the flexible printed circuit board 20 abuts against the reinforcing board 51, being the reinforcing structure, and meanwhile the rope sleeve 10 is further provided with a reinforcing line as the reinforcing structure, independent of the flexible printed circuit board 20. The material of the reinforcing structure is one of or a combination of polyimide (PI), stainless steel, aluminum foil, polyester (PET), fiberglass (FR), polytetrafluoroethylene (PTFE), polyethylene (PE), polycarbonate (PC), and polystyrene (PS), thereby ensuring the rope body endures a relatively large tension without generating an open circuit and has good folding resistance and tensile properties.

In the present embodiment, a hollow part of the rope sleeve 10 is filled with a silicone material mixed with phosphor, wherein a component of the phosphor includes a fluorescent material such as aluminate, silicate, nitride, and oxynitride. The component of the silicone material is an amorphous silicon dioxide polymer whose backbone is a SI—O bond and whose molecular formula is mSiO₂.nH₂O (m:n is a ratio of silicon dioxide molecules to water molecules), and a range of a solidification and a use temperature is from −100° C.-250° C.

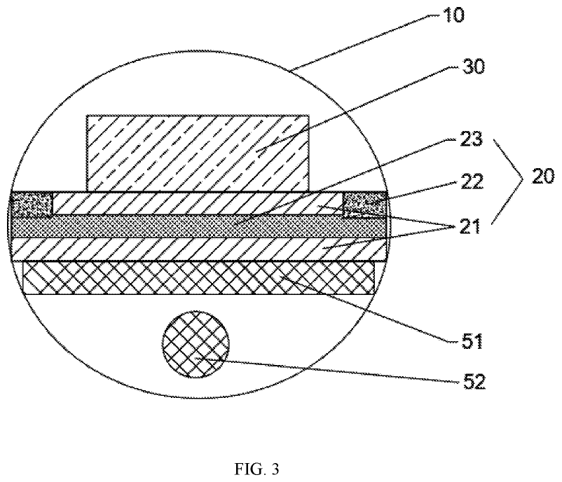

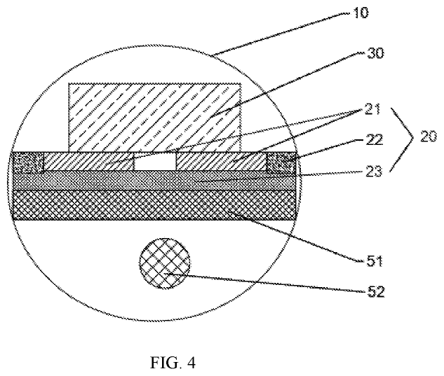

In the present embodiment, FIG. 3 shows a schematic sectional view of the lighting rope for the accessory of the present embodiment. The flexible printed circuit board 20 of the present embodiment is made of copper foil and is a multilayer circuit structure. Specifically, a two-layered circuit structure is used as an example, and the flexible printed circuit board 20 is a hybrid circuit, thereby making the LEDs 30 mutually independent of each other, without being affected by an open circuit so the product has high reliability. Certainly, the copper-coating layer 21 can also have a structure with more than two layers. Alternatively, the flexible printed circuit board 20 of the present embodiment may have a single-layered structure, as shown in FIG. 4.

To further protect the inner circuit, a surface of the flexible printed circuit board 20 of the present embodiment is wrapped with an insulation heat shrinkable film 22 by a film wrapping process. That is, the surface of the flexible printed circuit board 20 is wrapped with an insulation heat shrinkable film 22. The material of the insulation heat shrinkable film 22 is generally polyester film (MYLAR) and polytetrafluoroethylene (PTFE) and has certain functions such as waterproofing, insulating, and protecting the inner circuit. In addition, the flexible printed circuit board 20 of the present embodiment further includes a bottom insulation heat shrinkable film 23 provided on a bottom part of the flexible printed circuit board. The bottom insulation heat shrinkable film 23 is located between two copper-coating layers 21. The reinforcing board 51 is located on a bottom of the bottom insulation heat shrinkable film 23. The bottom insulation heat shrinkable film 23 and the surface insulation heat shrinkable film 22 may be made of the same material. The flexible printed circuit board 20 may be formed by means of laser cutting. Apart from the control unit and the power supply part, a width of a part of the flexible printed circuit board used for the bead string can be precisely controlled to be below 1.0 mm, which makes the flexible printed circuit board suitable/ready for mass production.

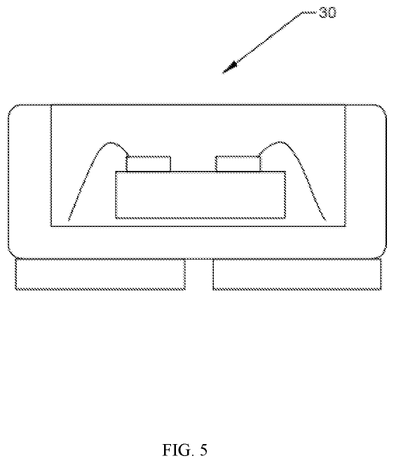

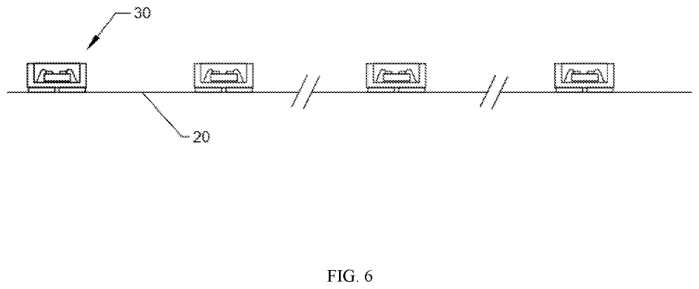

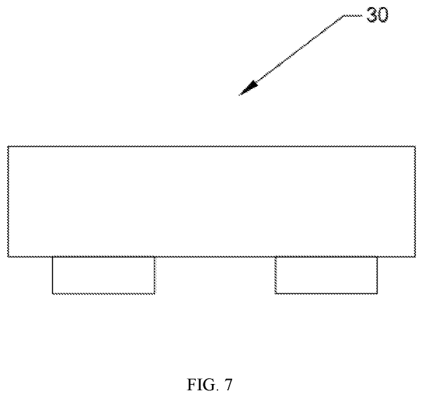

In the present embodiment of FIG. 5, the LEDs 30 are encapsulated in LED beads. The LEDs 30 are welded on the same side of the flexible printed circuit board 20. An electrode is matched with the power supply battery on the flexible printed circuit board 20 and is provided with a conductive protrusion (not shown), thereby facilitating electrical conduction. FIG. 6 is a schematic diagram showing the LED beads welded on the same side of the flexible printed circuit board 20. Certainly, the LEDs 30 may also be LED chips as shown in FIG. 6. FIG. 7 is a schematic diagram showing the LED chips provided on the same side of the flexible printed circuit board 20.

In the present embodiment, the LEDs 30 are welded on the flexible printed circuit board 20 to form a lighting core. The heat shrinkable film wrapping process is carried out on the lighting core and the rope sleeve 10 to form the lighting rope 1. A welding temperature of a solder used for the LEDs 30 and the flexible printed circuit board 20 is larger than the process temperature of the heat shrinkable film wrapping process of the lighting core and the rope sleeve 10, thereby preventing the solder of the LED chips from softening and melting when the temperature reaches the shrinking temperature of the rope sleeve 10.

The LEDs 30 controlled by the power supply control unit 40 have one or more of the following lighting modes: a constant lighting mode, a gradient lighting mode, a round-robin lighting mode, and a flashing lighting mode in order to select a needed lighting mode.

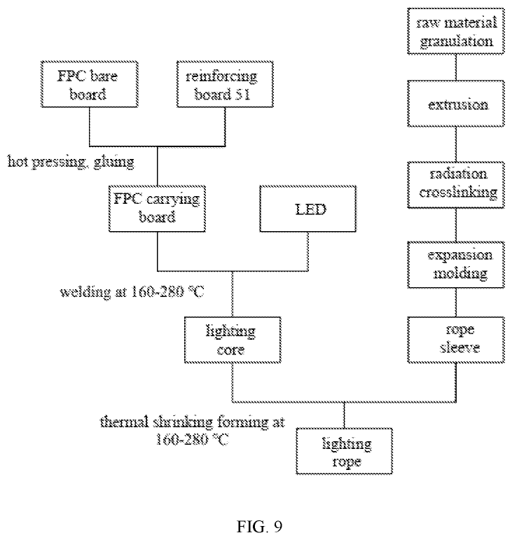

As shown in FIG. 9, a process of forming the lighting rope 1 for the accessory of the present embodiment is as follows. First, a bare board of the flexible printed circuit board (FPC board) 20 is attached to the reinforcing board 51 by heat pressing to form an FPC carrying board, and then the LEDs 30 are welded onto the FPC carrying board. The welding temperature is selected to be from 160° C. to 280° C., and the FPC carrying board welded with the LEDs 30 forms the lighting core. On the other hand, the rope sleeve 10 is manufactured by means of granulation, extrusion, radiation crosslinking and expansion molding of a raw material. Finally, the manufactured lighting core is sleeved with the rope sleeve 10 and performing the heat shrinking process to form the lighting rope, where the heat shrinking temperature is preferably from 100° C. to 160° C.

The preferred embodiments of the present invention are described as above. It should be understood that the present invention is not limited within the description disclosed by the present invention and is not considered to exclude other embodiments, but can be applicable to various other combinations, modifications, and environments. Moreover, the present invention can be modified within the scope of the concept of the present invention, according to the above-mentioned teachings or the technology and knowledge in the related art. Various changes and modifications made by those skilled in the art, without departing from the spirit and scope of the present invention, are intended to be within the scope of protection as defined by the appended claims of the present invention.

What is claimed is:

1. A lighting rope for an accessory, comprising: a power supply control unit, a rope sleeve, and a flexible printed circuit board provided inside and extending along the rope sleeve, wherein the flexible printed circuit board is sleeved with the rope sleeve by using a heat shrinkable film wrapping process, the flexible printed circuit board is provided in a length direction with a plurality of light-emitting diodes (LEDs) arranged at intervals, the power supply control unit comprises a push button and a power supply battery, and the plurality of LEDs are powered by the power supply battery and controlled by the push button to emit light.

2. The lighting rope for the accessory according to claim 1, wherein a base material for the rope sleeve is one of polyvinylidene difluoride (PVDF), polyethylene (PE), ethylene-vinyl acetate (EVA), polyvinyl chloride (PVC), polyvinylidene chloride (PVDC), polytetrafluoroethylene (PTFE), and ethylene propylene diene terpolymer (EPDM).

3. The lighting rope for the accessory according to claim 1, wherein a process temperature of the heat shrinkable film wrapping process for the rope sleeve is less than a welding temperature at which the plurality of LEDs are mounted onto the flexible printed circuit board.

4. The lighting rope for the accessory according to claim 1, wherein the flexible printed circuit board is a single-layer structure or a multilayer structure, and the flexible printed circuit board is a hybrid circuit.

5. The lighting rope for the accessory according to claim 1, wherein a reinforcing structure for reinforcing is further provided inside the rope sleeve, the reinforcing structure abuts against the flexible printed circuit board and/or the reinforcing structure is mutually independent of the flexible printed circuit board, and a material of the reinforcing structure is one of or a combination of polyimide (PI), stainless steel, aluminum foil, polyester (PET), fiberglass (FR), polytetrafluoroethylene (PTFE), polyethylene (PE), polycarbonate (PC), and polystyrene (PS).

6. The lighting rope for the accessory according to claim 1, wherein the plurality of LEDs are provided on the side of the flexible printed circuit board, and an electrode matched with the power supply battery on the flexible printed circuit board is provided with a conductive protrusion.

7. The lighting rope for the accessory according to claim 1, wherein a hollow part of the rope sleeve is filled with a silicone material mixed with phosphor.

8. The lighting rope for the accessory according to claim 1, wherein the plurality of LEDs are LED chips or encapsulated LED beads, and the plurality of LEDs are mounted on the flexible printed circuit board by a normal welding or a flip-chip welding.

9. The lighting rope for the accessory according to claim 1, wherein the plurality of LEDs are mounted on the flexible printed circuit board to form a lighting core, and the heat shrinkable film wrapping process is carried out on the lighting core and the rope sleeve to form the lighting rope.

10. The lighting rope for the accessory according to claim 1, wherein the plurality of LEDs are controlled by the power supply control unit to have one or more of the following lighting modes: a constantly lighting mode, a gradient lighting mode, a round-robin lighting mode, and a flashing lighting mode.
